(19) United States
(12) Patent Application Publication
(10) Pub. No.: US 2022/0278234 A1
(43) Pub. Date: Sep. 1, 2022

(54) THIN FILM TRANSISTOR

(71) Applicant: JUSUNG ENGINEERING CO., LTD., Gwangju-Si, Gyeonggi-Do (KR)

(72) Inventors: Jae Wan LEE, Gwangju-Si, Gyeonggi-Do (KR); Yong Hyun KIM, Gwangju-Si, Gyeonggi-Do (KR); Chang Kyun PARK, Gwangju-Si, Gyeonggi-Do (KR); Dong Hwan LEE, Gwangju-Si, Gyeonggi-Do (KR)

(21) Appl. No.: 17/620,113

(22) PCT Filed: Jul. 3, 2020
(86) PCT No.: PCT/KR2020/008749

§ 371 Date: Dec. 16, 2021

(30) Foreign Application Priority Data
Jul. 5, 2019 (KR) 10-2019-0081423

(51) Int. Cl. H01L 29/786; H01L 29/417

(52) U.S. Cl. CPC H01L 29/7869; H01L 29/78618; H01L 29/41733

(57) ABSTRACT

The present disclosure relates to a thin film transistor, and more particularly, to a thin film transistor in which a metal oxide thin film is used as an active layer. A thin film transistor including a gate insulating film and an active layer formed between source and drain electrodes, wherein the active layer includes: a first metal oxide thin film; a second metal oxide thin film provided between the first metal oxide thin film and the gate insulating film and having lower electrical conductivity than the first metal oxide thin film; and a third metal oxide thin film provided between the first metal oxide thin film and the source and drain electrodes and having lower electrical conductivity than the first metal oxide thin film.

### TECHNICAL FIELD

The present disclosure relates to a thin film transistor, and more particularly, to a thin film transistor in which a metal oxide thin film is used as an active layer.

### BACKGROUND ART

Thin film transistors (TFTs) are used for circuits for independently driving respective pixels in display devices such as liquid crystal display (LCD) devices or organic electroluminescent (EL) devices.

Such thin film transistors are formed together with gate lines and data lines on a lower substrate of a display device. That is, the thin film transistors are each composed of a gate electrode which is a portion of a gate line, an active layer used as a channel, source and drain electrodes which are portions of a data line, a gate insulating film, etc.

The active layer of the thin film transistor formed a channel region between the gate electrode and the source and drain electrodes, and was formed by using amorphous silicon or crystalline silicon. However, the substrate of a thin film transistor using silicon should use a glass substrate, and hence cannot be bent as well as having a large weight. Thus, the substrate has a limitation in that the substrate cannot be used for a flexible display device. In addition, there have been increasing demands for applying, to an active layer, a crystalline thin film having a high carrier concentration and excellent electrical conductivity to achieve a high speed element, that is, to improve mobility. To this end, research on technology in which a metal oxide thin film is used as an active layer has been actively carried out.

### RELATED ART DOCUMENTS

(Patent document 1) KR10-2004-0013273 A

### DISCLOSURE

### Technical Problem

The present disclosure provides a thin film transistor, in which a metal oxide thin film is used as an active layer, and thus may improve stability while having high mobility.

### Technical Solution

In accordance with an exemplary embodiment, a thin film transistor including a gate insulating film and an active layer formed between source and drain electrodes, wherein the active layer includes: a first metal oxide thin film; a second metal oxide thin film provided between the first metal oxide thin film and the gate insulating film and having lower electrical conductivity than the first metal oxide thin film; and a third metal oxide thin film provided between the first metal oxide thin film and the source and drain electrodes and having lower electrical conductivity than the first metal oxide thin film.

The first metal oxide thin film may be formed of an oxide of a first metal material including indium (In) and zinc (Zn), the second metal oxide thin film may be formed of an oxide of a second metal material including indium (In), gallium (Ga), and zinc (Zn), and the third metal oxide thin film may be formed of an oxide of a third metal material including indium (In), gallium (Ga) and zinc (Zn).

The first metal oxide thin film may include indium (In) n a content of equal to or greater than approximately 30 at % and less than approximately 80 at % with respect to the entirety of the first metal material.

The second metal oxide thin film may include gallium (Ga) in a content of equal to or greater than approximately 30 at % and less than approximately 60 at % with respect to the entirety of the second metal material, and the third metal oxide thin film may include gallium (Ga) in a content of equal to or greater than approximately 30 at % and less than approximately 60 at %.

The third metal oxide thin film may have lower electrical conductivity than the second metal oxide thin film.

An amount of gallium contained in the third metal material may be greater than an amount of gallium contained in the second metal material.

The first metal material may further include gallium (Ga), and the first metal oxide thin film may include the gallium in an amount of less than approximately 30 at % with respect to the entirety of the first metal material.

The first metal oxide thin film may include the gallium (Ga) contained in an amount of equal to or greater than approximately 20 at % and less than approximately 60 at % with respect to the entirety of the gallium (Ga) contained in the active layer.

A thickness of the second metal oxide thin film may be less than a thickness of the first metal oxide thin film, and a thickness of the third metal oxide thin film may be greater than the thickness of the first metal oxide thin film.

The first metal oxide thin film may be formed in a thickness of equal to or greater than approximately 100 Å and less than approximately 150 Å, the second metal oxide thin film may be formed in a thickness of less than 50 Å, and the third metal oxide thin film may be formed in a thickness of equal to or greater than approximately 150 Å and less than approximately 200 Å.

The first metal oxide thin film may include a zinc oxide (ZnO) thin film doped with first impurities, the second metal oxide thin film may include a zinc oxide (ZnO) thin film doped with first and second impurities, the third metal oxide thin film may include a zinc oxide (ZnO) thin film doped with the first and second impurities, the first impurities may include indium (In), and the second impurities may include at least one among gallium (Ga) and tin (Sn).

The first metal oxide thin film may be further doped with the second impurities.

The content of the gallium (Ga) may gradually vary.

The content of the gallium (Ga) may have two or more discontinuous values.

### Advantageous Effects

In accordance with a thin film transistor of an exemplary embodiment, the ratio of gallium in the metal oxide thin film that is configuring the active layer is adjusted to be different, and thus, a high-speed operation may be performed and stability may be improved.

In addition, when the active layer is configured a plurality of the metal oxide thin films, the ratio of gallium in the metal oxide thin films that are included the active layer are adjusted to be mutually different, and thus, a high-speed operation may be performed and stability may be improved.

That is, mobility may be improved by adjusting the component and thickness of the first metal oxide thin film that forms a main movement path of charges between the gate electrode and the source and drain electrodes, and the stability of the element may be improved by adjusting the component and thickness of the second metal oxide thin film that forms an interface between the gate insulating film and the first metal oxide thin film, and adjusting the component and thickness of the third metal oxide thin film that forms the interface between the first metal oxide thin film and the source and drain electrodes.

### BRIEF DESCRIPTION OF THE DRAWINGS

FIG. 1 is a view schematically illustrating a thin film transistor in accordance with an exemplary embodiment;

FIG. 2 is a view illustrating a state in which an active layer includes a metal oxide thin film in accordance with an exemplary embodiment;

FIG. 3 is a view schematically illustrating a thin film transistor in accordance with an exemplary embodiment; and

FIG. 4 is a schematic view showing a deposition device applied to manufacture a thin film transistor in accordance with an exemplary embodiment.

### DETAILED DESCRIPTION

Hereinafter, exemplary embodiments will be described in detail with reference to the accompanying drawings. However, the present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art.

It will be understood that it is referred to as being “on,” “connected to”, “stacked”, or “coupled to” another element, it may be directly on, connected, stacked, or coupled to the other element or intervening elements may be present.

In addition, spatially relative terms, such as “above” or “upper” and “below” or “lower” and the like, may be used herein for ease of description to describe one element or feature's relationship to another element(s) or feature(s) as illustrated in the drawings. Relative terms may be understood to be used to include other directions in addition to a direction described in the drawings. Here, the drawings may be exaggerated to describe the present disclosure in detail, and like reference numerals refer to like elements in the drawings.

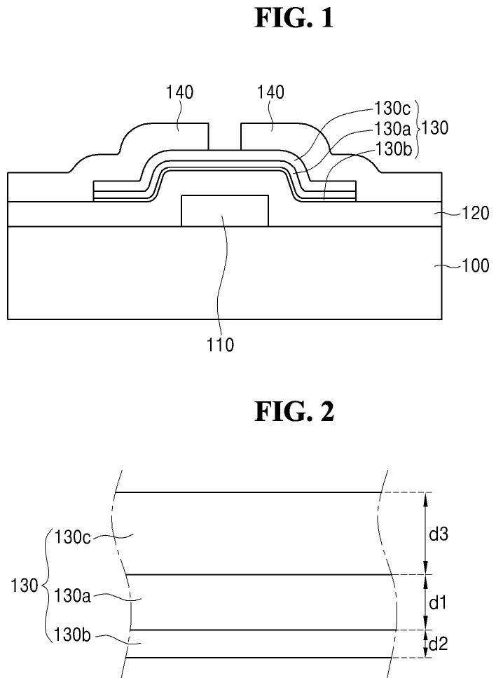

FIG. 1 is a view schematically illustrating a thin film transistor in accordance with an exemplary embodiment, and FIG. 2 is a view illustrating a state in which an active layer includes a metal oxide thin film in accordance with an exemplary embodiment.

Referring to FIGS. 1 and 2, a thin film transistor in accordance with an exemplary embodiment includes a gate insulating film 120, source and drain electrodes 140, and an active layer 130 formed between the gate insulating film 120 and the source and drain electrodes 140, wherein the active layer 130 includes: a first metal oxide thin film 130a; a second metal oxide thin film 130b provided between the first metal oxide thin film 130a and the gate insulating film 120 and having lower electrical conductivity than the first metal oxide thin film 130a; and a third metal oxide thin film 130c provided between the first metal oxide thin film 130a and the source and drain electrodes 140, and having lower electrical conductivity than the first metal oxide thin film 130a.

Here, as illustrated in FIG. 1, the thin film transistor in accordance with an exemplary embodiment may be a bottom gate-type thin film transistor that includes: a gate electrode 110 formed on a substrate 100; a gate insulating film 120 formed on the gate electrode 110; an active layer 130 formed on the gate insulating film 120; and source and drain electrodes 140 formed on the active layer 130 to be spaced apart from each other.

A transparent substrate may be used for the substrate 100, and for the substrate 100, a silicon substrate, a glass substrate, or a plastic substrate for a flexible display may be used. In addition, for the substrate 100, a reflective substrate may be used, and in this case, a metal substrate may be used. The metal substrate may be formed of stainless steel (SUS), titanium (Ti), or an alloy thereof. Meanwhile, when using a metal substrate for the substrate 100, it is desirable to form an insulating film on the metal substrate.

The gate electrode 110 may be formed by using a conductive material, at least one metal or an alloy thereof from among, for example, aluminum (Al), neodymium (Nd), silver (Ag), chromium (Cr), titanium (Ti), tantalum (Ta), molybdenum (Mo), or copper (Cu). In addition, the gate electrode 110 may be formed in not only a single layer or in a multilayer formed of a plurality of metal layers. That is, the gate electrode may be formed in a double layer including a metal layer of chromium (Cr), titanium (Ti), tantalum (Ta), molybdenum (Mo), or the like which have excellent physiochemical characteristics, and a metal layer based on aluminum (Al), silver (Ag), or copper (Cu) which have small resistivity.

The gate insulating film 120 may be formed on at least the gate electrode 110. That is, the gate insulating film 120 may be formed on the substrate 100 including the upper section and side section of the gate electrode 110. The gate insulating film 120 may be formed by using one or more insulating materials among inorganic insulating films including silicon oxide (SiO₂), silicon nitride (SiN), alumina (Al₂O₃), or zirconia (ZrO₂) that has excellent adhesion to a metallic material and have excellent insulation resistance.

The active layer 130 is formed between the gate insulating film 120 and the source and drain electrodes 140, and is formed so that at least a portion thereof overlaps the gate electrode 110. Here, the active layer 130 may be formed in a single metal oxide thin film 130 and also in a plurality of metal oxide thin films. The plurality of metal oxide thin films are formed in a plurality of metal oxide thin films including a first metal oxide thin film 130a, a second metal oxide thin film 130b, and a third metal oxide thin film 130c, and according to an exemplary embodiment, the second metal oxide thin film 130b may be formed between the gate insulating film 120 and the source and drain electrodes 140, the second metal oxide thin film 130b may be formed between the gate insulating film 120 and the first metal oxide thin film 130a, and the third metal oxide thin film 130c may be formed between the first metal oxide thin film 130a and the source and drain electrodes 140.

Here, the second metal oxide thin film 130b and the third metal oxide thin film 130c may have lower electrical conductivity than the first metal oxide thin film 130a. More specifically, the second metal oxide thin film 130b and the third metal oxide thin film 130c have higher resistance value than the first metal oxide thin film 130a, and thus, the second metal oxide thin film 130b and the third metal oxide thin film 130c may have lower electrical conductivity than the first metal oxide thin film 130a. Such the electrical conductivity of the first metal oxide thin film 130a, the second metal oxide thin film 130b, and the third metal oxide thin film 130c may be adjusted by controlling the type and content of metal elements included in each of the first metal oxide thin film 130a, the second metal oxide thin film 130b, and the third metal oxide thin film 130c, and the thickness of each the metal oxide thin films.

Here, the first metal oxide thin film 130a forms a main channel between the gate electrode 110 and the source and drain electrodes 140. The first metal oxide thin film 130a forms a main movement path of a charge inside the active layer 130 when a voltage is applied to the gate electrode 110, and therefore needs to have relatively high electrical conductivity in order to improve mobility.

Mean while, the second metal oxide thin film 130b forms an interface between the gate insulating film 120 and the first metal oxide thin film 130a. In addition, the second metal oxide thin film 130b functions to prevent hydrogen (H) ions contained inside the gate insulating film 120 from being diffused to the first metal oxide thin film 130a. That is, in manufacturing a thin film transistor, hydrogen (H) ions should be present inside a thin film due to a used material and a process method, and these hydrogen (H) ions have a merit of ensuring operation stability by filling a vacant region inside the active layer 130, but causes a limitation of deteriorating an interfacial charge characteristic when excessive hydrogen (H) ions are diffused from the gate insulating film 120. Accordingly, the second metal oxide thin film 130b is required to have improved stability, and need to have low electrical conductivity than the first metal oxide thin film 130a.

The third metal oxide thin film 130c forms an interface between the first metal oxide thin film 130a and the source and drain electrodes 140. In addition, the third metal oxide thin film 130c functions to shield hydrogen (H) ions and hydroxyl (OH) ions that infiltrate from an external environment. Such the third metal oxide thin film 130c is to prevent a change into a conductor caused by forming a channel, and to this end, the third metal oxide thin film 130c is required to have high stability, and needs to have lower electrical conductivity than the first metal oxide thin film 130a.

At this point, the second metal oxide thin film 130b may have higher electrical conductivity than the third metal oxide thin film 130c. As described above, the second metal oxide thin film 130b is provided to a position adjacent to the gate insulating film 120. Accordingly, charges are accumulated to the second metal oxide thin film 130b as a voltage is applied to the gate electrode 110, and thus, a main movement path is formed through the first metal oxide thin film 130a, and therefore the second metal oxide thin film 130b is formed to have higher electrical conductivity than the third metal oxide thin film 130c. In addition, the third metal oxide thin film 130c is closely related to a change of the thin film transistor into a conductor. That is, when the electrical conductivity of the third metal oxide thin film 130c is high, there is a limitation in that the active layer 130 forms a charge movement path between the source and drain electrodes 140 regardless of a voltage applied to the gate electrode 110, and thus, the resistance of the third metal oxide thin film 130c needs to have a higher value than that of the second metal oxide thin film 130b.

Here, in the thin film transistor in accordance with an exemplary embodiment, the electrical conductivity of the first metal oxide thin film 130a, the second metal oxide thin film 130b, and the third metal oxide thin film 130c may be adjusted by controlling the types and contents of metal elements contained in each of the metal oxide thin films.

Indium (In) is a metal that has a relatively low band gap and a relatively high standard electrode potential, and has a characteristic of having improved mobility by lowering the resistance thereof and increasing the electrical conductivity thereof. Conversely, gallium (Ga) is a metal that has a relatively high band gap and a relatively low standard electrode potential, and has characteristic of having improved stability by increasing the resistance thereof and decreasing the electrical conductivity thereof.

Thus, the first metal oxide thin film 130a may be formed of an oxide of a first metal material that contains indium (In) and zinc (Zn) or contains indium (In), gallium (Ga) and zinc (Zn) in order to improve the mobility thereof, the second metal oxide thin film 130b may be formed of an oxide of a second metal material that contains indium (In), gallium (Ga) and zinc (Zn) in order to improve the stability thereof, and the third metal oxide thin film 130c may be formed of an oxide of a third metal material that contains indium (In), gallium (Ga) and zinc (Zn) in order to improve the stability thereof.

That is, the first metal oxide thin film 130a may include a zinc oxide (ZnO) thin film doped with indium (In) or gallium (Ga), the second metal oxide thin film 130b may include a zinc oxide (ZnO) thin film doped with indium (In) or gallium (Ga), and the third metal oxide thin film 130c may include a zinc oxide (ZnO) thin film doped with indium (In) or gallium (Ga). Here, indium (In) and gallium (Ga) may be doped on the zinc oxide (ZnO) thin film as impurities, and the gallium doped on to the zinc oxide (ZnO) thin film may be at least partially or entirely replaced by tin (Sn). Hereinafter, exemplary embodiments will be mainly described that contains gallium (Ga) in the second metal oxide thin film 130b and the third metal oxide thin film 130c, but the description below may also be applied as it is to a case of containing tin (Sn).

More specifically, the first metal oxide thin film 130a may include indium-zinc oxide (IZO: In—Zn—O) or indium-gallium-zinc oxide (IGZO: In-Ga—Zn-O), and the second metal oxide thin film 130b and the third metal oxide thin film 130c may include indium-gallium-zinc oxide (IGZO: In-Ga—Zn-O).

The first metal oxide thin film 130a may include indium (In) and zinc (Zn). In the first metal oxide thin film 130a, indium (In) may be included in a content of equal to or greater than approximately 30 at % (atomic %) and less than approximately 80 at %. Here, there is limitations in that when the content of indium is less than approximately 30 at %, the electrical conductivity decreases and the mobility degrades, and when the content of indium is equal to or greater than approximately 80 at %, the electrical conductivity increases more than necessary and leakage current and off current increase. Accordingly, in the first metal oxide thin film 130a, indium (In) may be included in a value within the range of equal to or greater than approximately 30 at % and less than approximately 80 at % inclusive with respect to the entirety of metal material, be included in at least two or more contents having discontinuous value within the range, or be included in continuously varying contents within the range. In this case, improved mobility may be achieved, and leakage current and off current may be minimized.

Here, when the first metal material that forms the first metal oxide thin film includes indium (In) and zinc (Zn), zinc (Zn) may be included in a content of approximately 20-70 at % (atomic %) with respect to the entirety of the first metal material.

In addition, the first metal material that forms the first metal oxide thin film 130a may further include gallium (Ga). That is, the first metal oxide thin film 130a may be formed of an oxide of a first metal material containing indium (Ga), gallium (Ga) and zinc (Zn), and at this point, in the first metal oxide thin film 130a, gallium (Ga) may be included in a content of less than approximately 30 at % with respect to the entirety of the first metal material. Gallium (Ga) may be included in the first metal material in order to improve stability, and when the content of gallium (Ga) is equal to or greater than approximately 30 at % with respect to the entirety of the first metal material, resistance rises too high, and thus, gallium (Ga) may be included in the first metal oxide thin film 130a in a content of greater than approximately 0 at % and less than approximately 30 at %. Meanwhile, in order to improve stability and maintain the electrical conductivity of the first metal oxide thin film 130a that forms the main channel, gallium (Ga) included in the first metal material may be included in a content of equal to or greater than approximately 20 at % and less than approximately 60 at % with respect to the gallium (Ga) included in the entirety of the active layer 130, be included in at least two or more contents having discontinuous values within the range, or be included in a content continuously varying within the range. The above description may be applied the same to a case in which the first metal oxide thin film 130a further contains tin (Sn) in place of gallium (Ga).

Meanwhile, in the second metal oxide thin film 130b, gallium (Ga) may be included in a content of equal to or greater than approximately 30 at % and less than approximately 60 at % with respect to the entirety of the second metal material in the second metal oxide thin film 130b. Here, when gallium (Ga) is included in a content less than approximately 30 at %, there is a limitation in that the characteristic related to stability such as negative bias temperature instability (NBTS), positive bias temperature instability (PBTI), or the like is degraded, and when gallium (Ga) is included in a content of equal to greater than approximately 60 at %, a porous film material is formed, and thus, the surface roughness increases and the mobility remarkably decreases. Accordingly, in the second metal oxide thin film 130b, gallium (Ga) may be included in a value within the range of equal to or greater than approximately 30 at % and less than approximately 60 at % with respect to the entirety of second metal material, be included in at least two or more contents having discontinuous value within the range, or be included in continuously varying contents within the range. In this case, the stability of an element may be improved.

In addition, in the third metal oxide thin film 130c, gallium (Ga) may be included in a content of equal to or greater than approximately 30 at % and less than approximately 60 at % with respect to the entirety of the third metal material in the third metal oxide thin film 130c. Here, when gallium (Ga) is included in a content of less than approximately 30 at %, there is a limitation in that a thin film transistor may easily become a conductor, and when included in a content of equal to or greater than approximately 60 at %, a porous film material is formed, and thus, there is limitations in that the surface roughness increases and the mobility remarkably decreases. Here, when gallium (Ga) is included in at least two contents having discontinuous values within the range of equal to or greater than approximately 30 at % and less than approximately 60 at %, or included in a content continuously vary within the range, the stability of an element may be improved as described above while preventing the change of a thin film transistor into a conductor.

The amount of gallium (Ga) included in the third metal material in the third metal oxide thin film 130c, may be more than the amount of gallium (Ga) included in the second metal material in the second metal oxide thin film 130b. As described above, the second metal oxide thin film 130b is formed to have higher electrical conductivity than the third metal oxide thin film 130c. Here, gallium (Ga) has a characteristic of raising resistance and decreasing electrical conductivity to improve stability. Thus, the amount of gallium (Ga) included in the third metal material in the third metal oxide thin film 130c is made to be more than the amount of gallium (Ga) included in the second metal material in the second metal oxide thin film 130b, and the stability of the third metal oxide film 130c may be improved compared to that of the second metal oxide thin film 130b, and the change of the thin film transistor into a conductor may be prevented.

Meanwhile, in the thin film transistor in accordance with an exemplary embodiment, the electrical conductivity of the first metal oxide thin film 130a, the second metal oxide thin film 130b, and the third metal oxide thin film 130c may be adjusted by controlling the thickness of each of the metal oxide thin films.

More specifically, the electrical conductivity of the first metal oxide thin film 130a may be controlled by adjusting the content of indium (In) contained in the first metal material that forms the first metal oxide thin film 130a. In addition, the electrical conductivity of the second metal oxide thin film 130b and the third metal oxide thin film 130c may be controlled by controlling the thicknesses of the second metal oxide thin film 130b and the third metal oxide thin film 130c. To this end, the thickness d2 of the second metal oxide thin film 130b may be smaller than the thickness d1 of the first metal oxide thin film 130a, and the thickness d3 of the third metal oxide thin film 130c may be greater than the thickness d1 of the first metal oxide thin film 130a.

The first metal oxide thin film 130a is provided to form a main channel between the gate electrode 110 and the source and drain electrodes 140, the second metal oxide thin film 130b and the third metal oxide thin film 130c are for stability of the element, and the first metal oxide thin film 130a is controlled to have a low resistance value and high electrical conductivity by increasing the content of indium (In) compared to those of the second metal oxide thin film 130b and the third metal oxide thin film 130c and decreasing the content of gallium (Ga) when including gallium (Ga).

On the other end, the second metal oxide thin film 130b is for the stability of the element, but the second metal oxide thin film 130b is provided to a position adjacent to the gate insulating film 120, and thus need to have electrical conductivity no smaller than a certain level. Thus, the content of indium (In) of the second metal thin film 130b is decreased compared to the first metal oxide thin film 130a, and the thickness d2 of the second metal oxide thin film 130b is formed to be smaller than the thickness d1 of the first metal oxide thin film 130a while increasing the content of gallium (Ga), and thus, the second metal oxide thin film has electrical conductivity no less than a certain level.

In addition, the third metal oxide thin film 130c is for stability of the element like the second metal oxide thin film 130b, but when the electrical conductivity of the third metal oxide thin film 130c is high, there is a limitation in that the thin film transistor becomes a conductor. Thus, in the third metal oxide thin film 130c, the content of indium (In) is decreased and the content of gallium (Ga) is increased, compared to those of the first metal oxide thin film 130a, and the thickness d3 of the third metal oxide thin film 130c is formed to be greater than the thickness d1 of the first metal oxide thin film 130a, and thus, the resistance is increased and the stability of the element is ensured. The first metal oxide thin film 130a may be formed in a thickness of equal to or greater than approximately 100 Å and less than approximately 150 Å, the second metal oxide thin film 130b may be formed in a thickness of less than 50 Å, and the third metal oxide thin film 130c may be formed in a thickness of equal to or greater than approximately 150 Å and less than approximately 200 Å.

The source and drain electrodes 140 are formed on the active layer 130, partially overlap the gate electrode 110, and are spaced apart from each other with the gate electrode 110 disposed therebetween. The source and drain electrodes 140b may be formed through the same process using mutually the same material, be formed by using a conductive material, and may be formed of at least one metal or an alloy thereof from among, for example, aluminum (Al), neodymium (Nd), silver (Ag), chromium (Cr), titanium (Ti), tantalum (Ta), or molybdenum (Mo). That is, the source and drain electrodes 140 may be formed of the same material, but may also be formed of other materials. In addition, the source and the drain electrodes 140 may be formed as not only a single layer but also a multilayer formed of a plurality of metal layers.

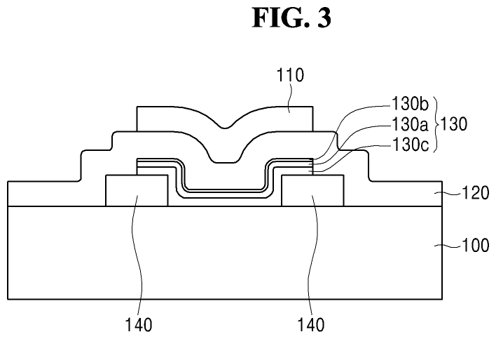

FIG. 3 is a view schematically illustrating a thin film transistor in accordance with an exemplary embodiment.

Referring to FIG. 3, a thin film transistor in accordance with another exemplary embodiment may be a top gate-type thin film transistor that includes: source and drain electrodes 140 that are formed to be spaced apart from each other on a substrate 100; an active layer 130 formed on source and drain electrodes; a gate insulating film 120 formed on the active layer; and a gate electrode 110 formed on the gate insulating film.

The above-mentioned statement related to FIGS. 1 and 2 may also be applied as it is to such the top gate-type thin film transistor. That is, even in the case of a thin film transistor in accordance with another exemplary embodiment, the active layer 130 may be formed of a plurality of metal oxide thin films, and in this case, a third metal oxide thin film 130c is positioned between the source and drain electrodes 140 and the first metal oxide thin film 130a, and a second metal oxide thin film 130b is positioned between the first metal oxide thin film 130a and the gate insulating film 120. As such, even in a case of a thin film transistor in accordance with another exemplary embodiment, only the laminating order of metal oxide thin films is different, and the statement described in the thin film transistor in accordance with an exemplary embodiment may be applied as it is, and thus, overlapped descriptions will be omitted.

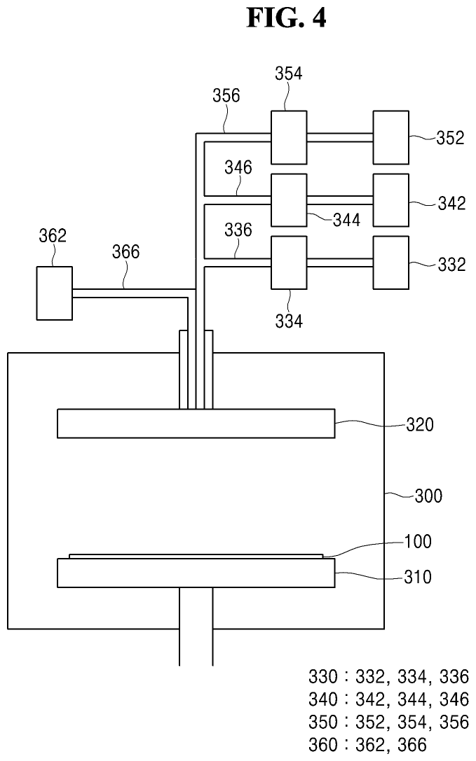

FIG. 4 is a view schematically showing a deposition device applied to manufacture a thin film transistor in accordance with an exemplary embodiment.

Referring to FIG. 4, a thin film transistor in accordance with an exemplary embodiment is manufactured by a deposition device that may form a plurality of metal oxide thin films in the same reaction chamber by performing a chemical vapor deposition process (CVD) or an atomic layer deposition process (ALD) or sequentially performing a chemical vapor deposition process (CVD) or an atomic layer deposition process (ALD).

The deposition device used in an exemplary embodiment includes: a reaction chamber 300 provided with a predetermined reaction space; a susceptor 310 provided on an inner lower side of the reaction chamber 300; an injector 320 provided on an inner upper side of the reaction chamber 300 so as to correspond to the susceptor 310; a first raw material gas supply part 330 for supplying an indium (In) gas; a second raw material gas supply part 340 for supplying a gallium (Ga) gas; a third raw material gas supply part 350 for supplying a zinc (Zn) gas, and a reaction gas supply part 360 for supplying an oxygen (O) gas. Here, a material including oxygen (O) may be used as the reaction gas, and O₂, N₂O, CO₂ excited in a plasma state or O₃ may also, of course, be used. In addition, although not shown, the deposition device may further include a purge gas supply part that supplies a purge gas such as an inert gas or the like.

Here, the first, second, third raw material gas supply parts 330. 340, and 350 may include: raw material storage parts 332, 342, and 352 that store each of the raw materials; bubblers 334, 344, and 354 that vaporize the raw materials and generate a raw material gas; and raw material supply pipes 336, 346, and 356 that form a supply path of the raw materials. In addition, the reaction gas supply part 360 may further include: reaction material storage part 362 that stores reaction materials and a reaction material supply pipe 366 that form the supply path of the reaction material, and may further include a bubbler when using H2O or the like as the reaction material. Meanwhile, the susceptor 310 may embed a heater (not shown) and a cooling means (not shown) and may maintain the substrate 100 at a process temperature. Here, a gate electrode, a gate insulating film or the like may be formed on the substrate 100, and at least one substrate 100 may be mounted on the susceptor 310.

Here, a first metal oxide thin film 130a of the thin film transistor in accordance with the exemplary embodiment may be formed by a chemical vapor deposition process (CVD) or an atomic layer deposition process (ALD) using the deposition device, and the second metal oxide thin film 130b and the third metal oxide thin film 130c may also be formed by a chemical vapor deposition process or an atomic layer deposition process (ALD) using the deposition device. Meanwhile, the first metal oxide thin film 130a may be formed by the chemical vapor deposition process (CVD) using the deposition device, and the second metal oxide thin film 130b and the third metal oxide thin film 130c may also, of course, be formed by the atomic layer deposition process (ALD) using the deposition device. The deposition device in accordance with the exemplary embodiment may deposit a thin film while maintaining uniform film quality by forming the active layer 130 through the chemical vapor deposition process or the atomic layer deposition process, and may easily form a multilayer-structure active layer by adjusting the supply amount of a raw material gas and a reaction gas.

At this point, the content of indium (In) and gallium (Ga) may gradually increase or decrease in the interface region of the second metal oxide thin film 130b and the interface region of the first metal oxide thin film 130a and the third metal oxide thin film 130c with respect to the second metal oxide thin film 130b, the first metal oxide thin film 130a, and the third metal oxide thin film 130c which are sequentially laminated. In addition, the content of indium (In) or gallium (Ga) may discontinuously or gradually increase or decrease inside each of the thin films of the second metal oxide thin film 130b, the first metal oxide thin film 130a, and the third metal oxide thin film 130c. This is because in the exemplary embodiment, a deposition process such as a chemical vapor deposition process, an atomic layer deposition process or the like is used for the active layer 130, and when the active layer 130 is formed by a sputtering process in which a target should be changed according to type of formed thin film, such a change in the content is not generated.

For example, when the first metal oxide thin film 130a includes indium-zinc oxide (IZO), an indium (In) gas and a zinc (Zn) gas are supplied through the first raw material gas supply part 330 and the third raw material gas supply part 350, and oxygen (O) gas may be supplied to the reaction chamber 300 through the reaction gas supply part 360. At this point, in the chemical vapor deposition process, a raw material gas and a reaction gas are simultaneously supplied to the reaction chamber 300. In addition, in an atomic layer deposition process, a raw material gas is supplied to the reaction chamber 300 to adsorb a raw material on the substrate 100. In addition, the supply of the raw material gas is stopped, and a purge gas such as an inert gas is supplied to purge a non-adsorbed raw material gas. Subsequently, oxygen (O) gas is supplied into the reaction chamber 300 through the reaction gas supply part 360 to oxidize the raw material adsorbed onto the substrate 100, and thereby forms a metal oxide thin film of an atomic layer. In addition, the supply of the reaction gas is stopped, and the purge gas such as an inert gas is supplied into the reaction chamber 300 to purge a non-reacted gas. Metal oxide thin films having predetermined thicknesses are formed by repeating, a plurality of times, the supply and purge of such the raw material gas and the supply and purge of the reaction gas.

Meanwhile, in the case in which the first metal oxide thin film 130a includes an indium-gallium-zinc oxide (IGZO) and in case of the second metal oxide thin film 130b and the third metal oxide thin film 130c that include an indium-gallium-zinc oxide (IGZO), there are only a difference in that an indium (In) gas, a gallium (Ga) gas, and a zinc (Zn) gas are used as a raw material gas and a difference of the supplied amounts of the gases. Thus, overlapped descriptions will be omitted.

Here, a process for forming the first metal oxide thin film 130a, the second metal oxide thin film 130b, and the third metal oxide thin film 130c may be performed inside the same reaction chamber 300. In addition, in order to form the above-mentioned bottom gate-type thin film transistor, there is only a difference in that the third metal oxide thin film 130c is formed on the source and drain electrodes 140, and the first metal oxide thin film 130a is formed after forming the second metal oxide thin film 130b. Therefore, overlapped descriptions will be omitted.

As such, in accordance with a thin film transistor of an exemplary embodiment, the electrical conductivity of the plurality of metal oxide thin films 130a, 130b, and 130c that are included in the active layer 130 are adjusted to be mutually different, and thus, a high-speed operation may be performed and stability may be improved.

That is, mobility may be improved by adjusting the component and thickness of the first metal oxide thin film 130a that forms a main movement path of charges between the gate electrode 110 and the source and drain electrodes 140, and the stability of the element may be improved by adjusting the component and thickness of the second metal oxide thin film 130b that forms an interface between the gate insulating film and the first metal oxide thin film 130a, and adjusting the component and thickness of the third metal oxide thin film 130c that forms the interface between the first metal oxide thin film 130a and the source and drain electrodes 140.

In the above, preferable exemplary embodiments have been described and illustrated using specific terms, but such the terms are only used for clearly describing the present disclosure, and the exemplary embodiments and the described technical terms may obviously be modified and varied without departing from the technical concept and scope of claims below. Such variously modified embodiments should not be interpreted separate from the spirit and scope of the present disclosure, and but to be included in the claims of the present disclosure.

1. A thin film transistor comprising a gate insulating film and an active layer formed between source and drain electrodes, wherein the active layer comprises:
a first metal oxide thin film;
a second metal oxide thin film provided between the first metal oxide thin film and the gate insulating film and having lower electrical conductivity than the first metal oxide thin film; and
a third metal oxide thin film provided between the first metal oxide thin film and the source and drain electrodes and having lower electrical conductivity than the first metal oxide thin film.

2. The thin film transistor of claim 1, wherein:
the first metal oxide thin film is formed of an oxide of a first metal material comprising indium (In) and zinc (Zn);
the second metal oxide thin film is formed of an oxide of a second metal material comprising indium (In), gallium (Ga), and zinc (Zn); and
the third metal oxide thin film is formed of an oxide of a third metal material comprising indium (In), gallium (Ga) and zinc (Zn).

3. The thin film transistor of claim 2, wherein the first metal oxide thin film comprises indium (In) in a content of equal to or greater than approximately 30 at % and less than approximately 80 at % with respect to the entirety of the first metal material.

4. The thin film transistor of claim 2, wherein:
the second metal oxide thin film comprises gallium (Ga) in a content of equal to or greater than approximately 30 at % and less than approximately 60 at % with respect to the entirety of the second metal material; and
the third metal oxide thin film comprises gallium (Ga) in a content of equal to or greater than approximately 30 at % and less than approximately 60 at %.

5. The thin film transistor of claim 2, wherein the third metal oxide thin film has lower electrical conductivity than the second metal oxide thin film.

6. The thin film transistor of claim 5, wherein an amount of gallium (Ga) contained in the third metal material is greater than an amount of gallium (Ga) contained in the second metal material.

7. The thin film transistor of claim 3, wherein the first metal material further comprises gallium (Ga) and the first metal oxide thin film comprises the gallium in an amount of less than approximately 30 at % with respect to the entirety of the first metal material.

8. The thin film transistor of claim 7, wherein the first metal oxide thin film comprises the gallium (Ga) in an amount of equal to or greater than approximately 20 at % and less than approximately 60 at % with respect to the entirety of the gallium (Ga) contained in the active layer.

9. The thin film transistor of claim 2, wherein a thickness of the second metal oxide thin film is less than a thickness of the first metal oxide thin film, and a thickness of the third metal oxide thin film is greater than the thickness of the first metal oxide thin film.

10. The thin film transistor of claim 9, wherein:
the first metal oxide thin film is formed in a thickness of equal to or greater than approximately 100 Å and less than approximately 150 Å;
the second metal oxide thin film is formed in a thickness of less than 50 Å; and
the third metal oxide thin film is formed in a thickness of equal to or greater than approximately 150 Å and less than approximately 200 Å.

11. The thin film transistor of claim 1, wherein:
the first metal oxide thin film comprises a zinc oxide (ZnO) thin film doped with first impurities;
the second metal oxide thin film comprises a zinc oxide (ZnO) thin film doped with first and second impurities;
the third metal oxide thin film comprises a zinc oxide (ZnO) thin film doped with the first and second impurities, the first impurities comprise indium (In); and
the second impurities comprise at least one among gallium (Ga) and tin (Sn).

12. The thin film transistor of claim 11, wherein the first metal oxide thin film is further doped with the second impurities.

13. The thin film transistor of claim 2, wherein the content of the gallium (Ga) gradually varies.

14. The thin film transistor of claim 2, wherein the content of the gallium (Ga) has two or more discontinuous values.
